(19) United States
(12) Patent Application Publication
(10) Pub. No.: US 2003/0058022 A1
(43) Pub. Date: Mar. 27, 2003

(54) DEVICE AND METHOD FOR CONTROLLING VOLTAGE VARIATION

(76) Inventors: RAJENDRAN NAIR, HILLSBORO, OR (US); VIVEK K. DE, BEAVERTON, OR (US)

Correspondence Address: SCHWEGMAN, LUNDBERG, WOESSNER & KLUTH, P.A., P.O. BOX 2938, MINNEAPOLIS, MN, 55402, US

(21) Appl. No.: 09/460,742

(22) Filed: Dec. 14, 1999

(51) Int. Cl. H03L 5/00

(52) U.S. Cl. 327/310

(57) ABSTRACT

Electronic devices having voltage variable capacitances are formed using CMOS fabrication processes. The devices are capable of decreasing noise of one polarity and amplifying noise of the opposite polarity. For one embodiment, a transistor having a gate oxide layer is operated in the depletion region to form a capacitive device. In an alternate embodiment, a CMOS transistor having an n-type substrate, all p-type polysilicon gate, an n-type source and drain, and a gate oxide layer is operated in the depletion region to form a capacitive device. For one embodiment, the disclosed devices are used in circuits for decoupling multiple voltage power supplies. In an alternate embodiment, the devices are used in circuits for damping power supply grid network resonances. In still another alternate embodiment, the devices are used in circuits for decoupling noise in power supply signals operating at low voltages.

### FIELD OF THE INVENTION

This invention relates to controlling voltage variations, and more particularly to using voltage variable capacitors to control voltage variations in electronic systems.

### BACKGROUND OF THE INVENTION

As synchronous digital systems are operated at lower voltages, multiple voltages, and higher frequencies, and as the number of logic cells that make up the systems increase, new problems arise in supplying power to the systems. Some of the problems include decoupling multiple voltage power supplies, damping power supply grid network resonances, and decoupling noise in power supply signals operating at low voltages.

For digital systems fabricated using mixed technologies and multiple voltages on a single substrate, the acceptable variation in the voltages are becoming more complex. For example, a system specification may define acceptable variations that are asymmetrical in the voltages. In a system requiring a 1.8 volt power supply and a 1.0 volt power supply, the 1.0 volt power supply may be required to maintain a value above 1.02 volts while the 1.8 volt supply may be permitted to rise to 2.0 volts. Digital systems having such specifications are typically decoupled by connecting a number of individual capacitive elements to each power supply voltage line near the logic cells being powered. Unfortunately, fabricating a number of separate capacitive elements for each cell and for each power supply line is very expensive in terms of space on the surface of the substrate.

Synchronous digital systems, such as microprocessors, packaged using controlled collapse chip connection technology can have hundreds of power connection points coupled to hundreds of thousands of digital cells decoupled by hundreds of thousands of fixed capacitors. The circuit formed by the power supply, the power lines, the parasitic inductances and capacitors, the power connection points, the digital cells, and the fixed capacitors form a power connection grid network. For large transient current events that occur in synchronous digital systems, the network can experience resonant oscillations. During the development of synchronous digital systems, simulations of the logic circuits that comprise the system are run to identify sequences of operations that result in large transient current events capable of producing resonant oscillations. Capacitors are added to the power connection grid network to reduce the magnitude of the current events and damp out any resulting resonant oscillations. Unfortunately, simulations seldom reflect the actual operating conditions of a complex circuit, and for complex synchronous digital systems it is difficult to simulate all possible modes of operations in a way that guarantees that resonant oscillations will not occur during the operation of the system.

Synchronous digital systems implemented as integrated circuits on a semiconductor substrate periodically demand large amounts of current. This demand is supplied by fixed capacitors located on the substrate and charged to a nominal operating voltage. As long as the variation in the nominal operating voltage is less than about 10% of the operating voltage, the logical operation of the synchronous digital system is unaffected. However, the trend in the design of synchronous digital systems is to reduce the nominal operating voltage and the absolute variation in the nominal operating voltage. Unfortunately, at the same time the acceptable variation in the nominal operating voltage is decreasing, the number of switching circuits on the substrate is increasing. Increasing the number of switching circuits increases the demand for current in the switching circuits, which increases the noise in the system. One solution to this problem is to increase the number of fixed capacitors coupled to the switching circuits. Unfortunately, for complex synchronous digital systems, such as microprocessors, the fixed capacitors already occupy a large percentage of the substrate area

For these and other reasons there is a need for the present invention.

### SUMMARY OF THE INVENTION

In some embodiments, the invention includes a noise reduction device comprising complementary metal-oxide semiconductor (CMOS) transistor. The transistor is operable as a two-terminal device in a depletion mode and has a non-linear voltage variation for charge being removed at a constant rate. The transistor is formed in an n-type substrate having an n-type drain, an n-type source, an p-type polysilicon gate, and a gate oxide layer.

Other embodiments are described and claimed below.

### BRIEF DESCRIPTION OF THE DRAWINGS

FIG. 1A is a schematic diagram of a metal oxide semiconductor field effect transistor configured to operate as a voltage variable capacitor.

FIG. 1B is a graph of a typical MOSFET capacitance versus voltage curve.

FIG. 1C is a graph of the noise across a MOSFET operating in the depletion mode and coupled to a noisy voltage signal versus the capacitor noise across a MOSFET operating in the inversion mode and coupled to the noisy voltage signal.

FIG. 2A is an illustration of one embodiment of an electronic device of the present invention.

FIG. 2B is an illustration of one embodiment of a an electronic device of the present invention configured in a circuit to decouple a high voltage level.

FIG. 3 is an illustration of schematic diagram of one embodiment of a circuit of suitable for use in damping resonant oscillations in a power supply grid.

FIG. 4 is a schematic diagram of one embodiment of a circuit suitable for use in controlling the voltages on a high voltage node and a low voltage node.

FIG. 5 is one embodiment of energy source having a unidirectional noise source signal coupled to a load and a device formed on a substrate.

### DESCRIPTION OF THE INVENTION

In the following detailed description of the preferred embodiments, reference is made to the accompanying drawings which form a part hereof, and in which is shown by way of illustration specific preferred embodiments in which the inventions may be practiced. These embodiments are described in sufficient detail to enable those skilled in the art to practice the invention, and it is to be understood that other embodiments may be utilized and that logical, mechanical and electrical changes may be made without departing from the spirit and scope of the present invention. The following detailed description is, therefore, not to be taken in a limiting sense, and the scope of the present invention is defined only by the claims.

Voltage variable capacitors are capable of decreasing noise signals of one polarity and increasing noise signals of the opposite polarity. A metal oxide semiconductor field effect transistor (MOSFET), fabricated and configured in the embodiments described below, is one type of active device that exhibits this property and can be applied to a variety of signal processing applications.

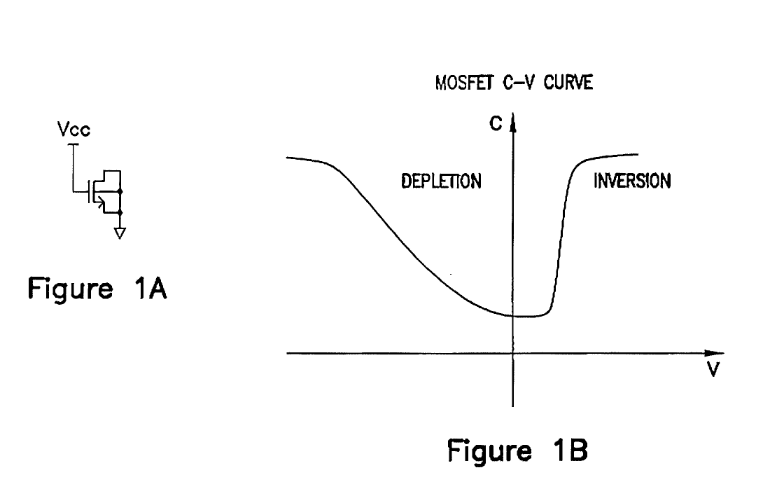

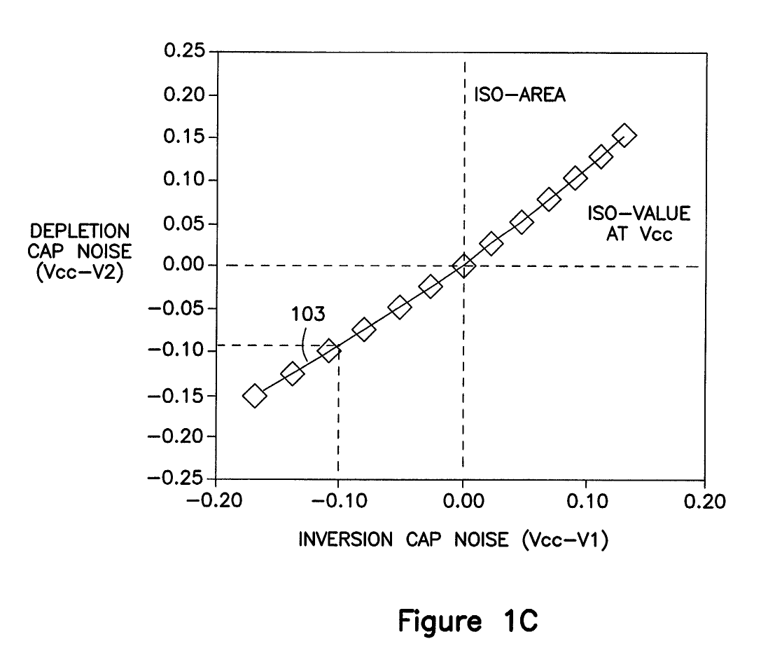

FIG. 1A is a schematic diagram of a metal oxide semiconductor field effect transistor configured to operate as a voltage variable capacitor. FIG. 1B is a graph of a typical MOSFET capacitance versus voltage curve. As can be seen from the graph, a MOSFET operating in the inversion mode has an approximately constant capacitance for changes in voltage, and a MOSFET operating in the depletion mode has a capacitance that varies with changes in voltage. In some applications, a MOSFET configured as a voltage variable capacitor provides superior noise performance when compared to a fixed value capacitor.

FIG. 1C is a graph of the noise in a MOSFET operating in the depletion mode and coupled to a noisy voltage signal versus the noise in a MOSFET operating in the inversion mode and coupled to the noisy voltage signal. The relationship between the depletion mode capacitor noise, vₙ₂(t), for a variable capacitance and the inversion mode capacitor noise, vₙ₁(t), for a constant capacitance is give by:

$${v}_{n2} ( t ) = \frac{a C o}{K} + \sqrt{{( \frac{a C o}{K} )}^{2} - \frac{2 C o}{K} {v}_{n1} ( t )} ,$$

where K is a proportionality factor relating the capacitance value of the voltage variable capacitance to the applied voltage, a is a scaling factor for scaling the capacitance value Co,

vₙ₁(t)=Vcc−v₁(t), and

vₙ₂(t)=Vcc−v₂(t).

v₁(t) is the node voltage of a capacitor being discharged by a constant current and is given by:

$${v}_{1} ( t ) = V c c - \frac{I t}{C o} .$$

v₂(t) is the node voltage of a variable capacitor being discharged by a constant current. And the capacitance of the voltage variable capacitance as a function of the voltage v₂(t) is give by:

c(v₂(t))=aCₒ−K(V_{cc}−v₂(t))

Referring to FIG. 1C, data point 103 shows that for an inversion mode capacitor having a noise value of about −0.10, the depletion mode capacitor has a noise value of less than −0.10. So, the MOSFET operating in the depletion mode and having a voltage variable capacitance characteristic is capable of reducing the noise level below the noise level for a MOSFET operating in the inversion mode having a fixed value capacitor. Since equation (1) is a general equation describing the relationship between a noise voltage signal at a node coupled to a fixed value capacitor and a noise voltage signal at a node coupled to a voltage variant capacitor, equation (1) is not is not limited to MOSFET embodiments.

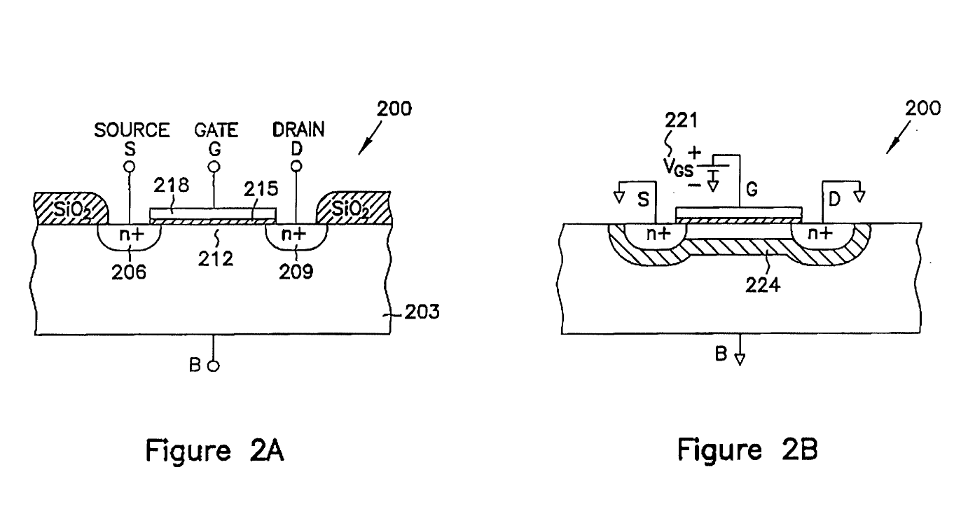

One embodiment of an electronic device having the superior noise performance described above is illustrated in FIG. 2A and described below. FIG. 2A shows an illustration of one embodiment of a MOSFET fabricated on substrate 203.

Substrate 203 includes a pair of spaced apart source and drain regions 206 and 209. Channel region 212 is located between source diffusion region 206 and drain diffusion region 209. Gate oxide layer 215 is formed above channel region 212. Polysilicon gate layer 218 is formed above gate oxide layer 215.

Substrate 203, which forms the foundation of electronic device 200, is not limited to a particular material. Substrate 203, for one embodiment, is a semiconductor, such as germanium or silicon. Alternatively, substrate 203 is gallium arsenide, silicon-on-sapphire, or any other cystalline or amorphous material suitable for use as a substrate in the manufacture of electronic devices. For the fabrication of CMOS devices, substrate 203 is preferably n-type silicon.

Diffusion regions 206 and 209, for one embodiment, are n+ regions formed in substrate 203. Dopants used in forming source diffusion region 206 and drain diffusion region 209 may be diffused, implanted, or deposited below the surface of substrate 203.

Gate oxide layer 215 is formed above channel region 212, and in one embodiment gate oxide layer 215 is thin. A thin gate oxide layer 215 has a thickness of between about 20 and 40 angstroms. A thickness of less than about 20 angstroms may result in manufacturing devices that have low yields, while a thickness of more than about 40 angstroms may result in a device frequency response that is lower than desired. Gate oxide layer 215 is not limited to a particular form of silicon oxide. For one embodiment, gate oxide layer 215 is a thermal oxide, such as silicon oxide (SiO), formed by oxidizing substrate 203. In an alternate embodiment, gate oxide layer 215 is silicon dioxide (SiO₂thermally grown to the required thickness. Alternatively, gate oxide layer 215 is formed above channel area 212 by chemical vapor deposition (CVD). Forming gate oxide layer 215 by CVD permits gate oxide layer 215 to have a higher doping level than thermally growing gate oxide layer 215.

Polysilicon gate layer 218, for one embodiment, is an p+region formed in polysilicon. The dopants for polysilicon gate layer 218 can be diffused, implanted or deposited into the polysilicon gate layer 218. For one embodiment, polysilicon layer 218 has a thickness of about 200 angstroms.

In operation, electronic device 200 is configured as shown in FIG. 2B. Source diffusion region 206, drain diffusion region 209, and semiconductor substrate 203 are coupled to a low voltage level, such as ground. Gate oxide layer 215 is coupled to high voltage level, V_{GS} 221, such as 1.3 volts. Depletion region 224, shown in FIG. 2B, forms a capacitance capable of being discharged at a constant rate. For the depletion region capacitance being discharged at a constant rate, the gate-to-drain voltage is given by:

$${v}_{2} ( t ) = V c c - \frac{a C o}{K} - \sqrt{{( \frac{a C o}{K} )}^{2} - \frac{2 I t}{K}} .$$

The gate-to-drain voltage, v₂(t), is a non-linear function of time.

Electronic device 200 shown in FIG. 2A is suitable for use in a variety of signal processing applications. However, devices configured as voltage variable capacitors and fabricated on an integrated circuit substrate are especially useful in damping resonant oscillations in voltage supply grid networks. Resonant oscillations are common in voltage supply grid networks included in synchronous digital systems, such as microprocessors.

A microprocessor power supply grid network can be driven into resonant oscillations by large transient current events, which occur during the normal synchronous operation of the microprocessor. Microprocessors are fabricated on a die and the frequency of the resonant oscillations is dependent on the inductance value between the power source and the die and the total capacitance seen on the die by the power supply grid network. Since high frequencies tend to die away quickly, faster damping of the power supply resonant behavior is obtained by transforming the power supply resonant spectrum to higher frequencies. One method of transforming the resonant spectrum to higher frequencies is to add voltage variable capacitors to the power supply grid network. Voltage variable capacitors are capable of decreasing noise of one polarity and increasing noise of the opposite polarity in response to a changing voltage. If the voltage variable capacitors are added to decrease noise when the voltage tends to decrease and to amplify noise when the voltage tends to increase, the frequency content of the power supply resonance is changed and the voltage stability of the power supply grid network is improved.

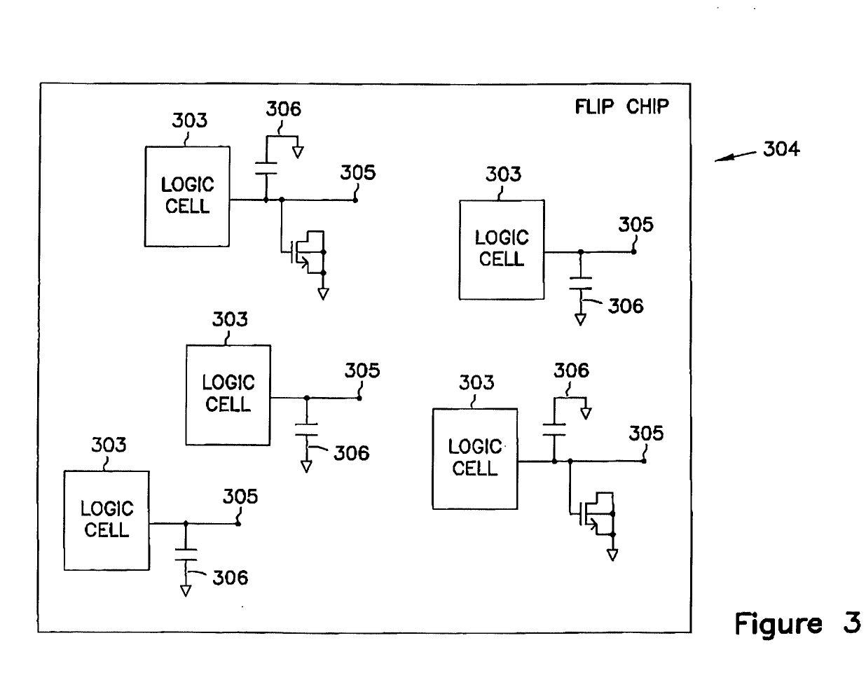

FIG. 3 is an illustration of a power supply grid network coupled to logic cells 303 located on an integrated circuit, such as flip-chip 304. The power supply grid network includes power supply voltage nodes 305, logic cells 303, and fixed decoupling capacitors 306. Each of the flip-chip logic cells 303 is decoupled by a number of fixed capacitors 306. For one embodiment, each of the number of fixed capacitors 306 has a capacitance value of about 100 femto-farads. The number of fixed capacitors is selected to provide a capacitance sufficient to avoid a significant voltage droop in voltage at power supply nodes 305 during the normal operation of logic cells 303. For one embodiment, the capacitance value of each of the variable capacitors 309 is about one-hundred nano-farads. The number of variable capacitors added to the power supply grid is selected based on the characteristics of the resonant voltages, which may be determined through simulation of the power supply grid network and through experiments performed on the power supply grid network coupled to flip chip 305.

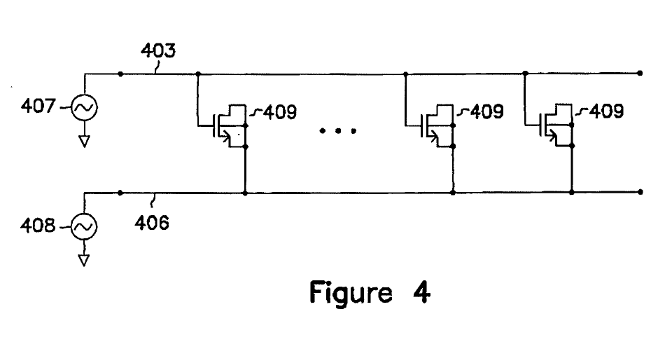

Processors, such as microprocessors, have core circuits fabricated at smaller dimensions and these core circuits typically operate off a lower voltage than non-core circuits. FIG. 4 is a schematic diagram of one embodiment of a circuit suitable for use in controlling the voltages on high voltage node 403 and low voltage node 406 provided by an energy sources 407 and 408 in a microprocessor power distribution circuit. For one embodiment, low voltage node 406 is coupled to 1 volt and high voltage node 403 is coupled to 1.8 volts. The plurality of voltage variable capacitors 409 connected between the high voltage node 403 and the low voltage node 406 prevents the low voltage node from falling below 1 volt. The plurality of voltage variable capacitors 409 also decreases noise in the direction that tends to increase the voltage on high voltage node 403. For one embodiment, the plurality of voltage variable capacitors are formed in MOSFETs coupled between high voltage node 403 and low voltage node 406. The source, drain, and body of each MOSFET are connected to high voltage node 403, and the gate of each MOSFET is connected to low voltage node 406.

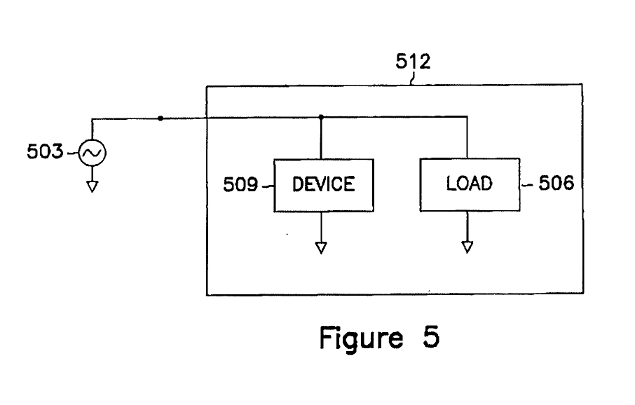

In an alternate embodiment, devices configured as voltage variable capacitors and fabricated on an integrated circuit substrate are useful in suppressing noise in a noise source having a unidirectional noise signal. FIG. 5 is one embodiment of energy source 503 having a unidirectional noise source signal coupled to load 506 and device 509 formed on substrate 512. For one embodiment, device 509 is a MOSFET configured as a variable voltage capacitor. For this embodiment, device 509 is capable of suppressing the unidirectional noise source signal more than a fixed voltage variable capacitor. This capability permits load 506 to be designed having lower noise margins and a lower operating voltage. Designing load 506 for operation at a lower operating voltage allows load 506 to operate longer on a depletable energy source, such as a battery.

Although specific embodiments have been illustrated and described herein, it will be appreciated by those of skill in the art that any arrangement which is calculated to achieve the same purpose may be substituted for the specific embodiment shown. This application is intended to cover any adaptations or variations of the present invention. Therefore, it is intended that this invention be limited only by the claims and the equivalents thereof.

What is claimed is:

1. A noise reduction device comprising:
a complementary metal-oxide semiconductor (CMOS) transistor operable as a two-terminal device in a depletion mode and having a non-linear voltage variation for charge being removed at a constant rate, the CMOS transistor is formed in an n-type substrate having an n-type drain, an n-type source, an p-type polysilicon gate, and a gate oxide layer.

2. The noise reduction device of claim 1, wherein the non-linear voltage variation is given by:
$${v}_{2} ( t ) = V c c - \frac{a C o}{K} - \sqrt{{( \frac{a C o}{K} )}^{2} - \frac{2 I t}{K}}$$

3. The noise reduction device of claim 2, wherein the gate oxide layer has a thickness of between about twenty and forty angstroms.

4. A circuit comprising:
a voltage node;
a ground node; and
a transistor coupled between the voltage node and the ground node, the transistor including an p-type, polysilicon ate is capable of decreasing noise signals above an absolute value of an operating voltage value at the voltage node and increasing, noise signals below the absolute value of the operating voltage value.

5. The circuit of claim 4, wherein the operating voltage value is between about 0.5 volts and about 1.5 volts.

6. The circuit of claim 5, further comprising:
a logic cell coupled to the voltage node and located in close proximity to the transistor.

7. A circuit comprising:
an energy source;
a processor having a plurality of nodes coupled to the energy source and forming a power supply grid having a number of resonant frequencies; and
a number of transistors coupled to at least one of the plurality of nodes such that at least one of the number of transistors is operable as a voltage variable capacitor capable of reducing the amplitude of resonant frequencies.

8. The circuit of claim 7, wherein the number of transistors is greater than about ten thousand.

9. A circuit comprising:
a die having a high voltage node and a low voltage node; and
a transistor coupled between the high voltage node and the low voltage node and operable for controlling a voltage at the low voltage node.

10. The circuit of claim 9, wherein the transistor has a gate, a drain, and a source, and the gate is coupled to the high voltage node and the source and the drain are coupled to the low voltage node.

11. A circuit comprising:
a substrate;
a load fabricated on the substrate;
an energy source coupled to the load, the energy source having an operating voltage and a unidirectional noise signal; and
an electronic device fabricated on the substrate and coupled to the load, the electronic device is capable of reducing the unidirectional noise signal more than a fixed capacitor having a capacitance value equal to the capacitance value of the electronic device operating at the operating voltage.

12. The circuit of claim 11, wherein file electronic device is a voltage variable capacitor.

13. The circuit of claim 11, wherein the electronic device is a MOSFET.

14. A circuit comprising:
a die;
a ground node located on the die;
a voltage node located on the die; and
an electronic device coupled between the ground node and the voltage node and capable of providing an, asymmetrical response to incremental voltage variations about an operational node voltage at the voltage node.

15. The circuit of claim 14, wherein incremental voltage variations of one polarity are damped and incremental voltage variations of the opposite polarity are amplified.

16. The circuit of claim 14, wherein the bias node voltage is about 1.3 volts.

17. An integrated circuit comprising:
a die;
a processor having a plurality of cells formed on the die; and
a number of electronic devices coupled to at least one of the plurality of cells and capable of damping positive voltage variations at the cell and amplifying negative voltage variations at the cell.

18. The integrated circuit of claim 17, wherein the plurality of cells are fabricated using a complementary metal-oxide semiconductor manufacturing process.

19. A method comprising:
receiving an energy signal having a noise component at a cell formed on a die; and
filtering the energy signal to form a filtered energy signal by decoupling the cell with a voltage variable capacitor.

20. The method of claim 19, wherein receiving an energy signal having a noise component at a cell comprises:
receiving a power supply signal at the cell.

21. The method of claim 19, wherein filtering the energy signal to form a filtered energy signal by decoupling the cell with a voltage variable capacitor comprises:
filtering the energy signal with at least one-hundred CMOS transistors operating in the depletion-accumulation region.

22. The method of claim 19, further comprising:
configuring at least one of the number of electronic devices to have a drain, a source, and a bulk connection coupled to a high voltage level and a gate coupled to a low voltage level.

23. A method comprising:
adding a number of electronic devices having a voltage variable capacitance to an electronic grid to suppress resonant frequencies in the electronic grid.

24. The method of claim 23, wherein adding a number of electronic devices comprises:
selecting an active electronic device; and
coupling the active electronic device between a high voltage level and a low voltage level at a logic cell.

25. The method of claim 23, further comprising:
locating at least one of the number of electronic devices between a logic cell and a decoupling capacitor.

26. A method comprising:
transforming a resonant frequency on a power supply grid network resonant at the resonant frequency to a higher frequency.

27. The method of claim 26, wherein transforming a resonant frequency on a power supply grid network resonant at the resonant frequency to a higher frequency comprises:
adding a voltage variable capacitor to the power supply grid network.

28. The method of claim 27, further comprising:
adding a plurality of CMOS transistors configured to operate in the depletion-accumulation region to the power supply grid network.
